(19) United States
(12) Patent Application Publication
(10) Pub. No.: US 2022/0366103 A1
(43) Pub. Date: Nov. 17, 2022

(54) METHOD AND SYSTEM FOR GENERATING A DESIGN OF A PRODUCT

(71) Applicant: Siemens Aktiengesellschaft, München (DE)

(72) Inventors: Chethan Ravi B R, Chickmagalur District, Karnataka (IN); Vidyabhushana Hande, Bangalore, Karnataka (IN); Vinay Ramanath, Bengaluru, Karnataka (IN); X Snehal, Udupi, Karnataka (IN)

(21) Appl. No.: 17/770,655

(22) PCT Filed: Oct. 30, 2019
(86) PCT No.: PCT/EP2019/079694

§ 371 Date: Apr. 21, 2022

(51) Int. Cl. G06F 30/20; G06Q 30/00

(52) U.S. Cl. CPC G06F 30/20; G06Q 30/018; G06F 2219/10

(57) ABSTRACT

A method and system for generating a design of a product is provided. The method includes obtaining a model of the product. The model is associated with a design of the product. The method includes simulating a model of the product with respect to an environmental sustainability of the product. The method includes generating simulation results indicative of behavior of the model with respect to the environmental sustainability. The simulation results comprise an environmental sustainability index of the product. The method includes determining whether the environmental sustainability index of the product satisfies an environmental sustainability threshold value. Further, the method includes generating a modified model of the product if the environmental sustainability index of the product satisfies the environmental sustainability threshold value.

### CROSS-REFERENCE TO RELATED APPLICATIONS

This application claims priority to PCT Application No. PCT/EP2019/079694, having a filing date of Oct. 30, 2019, the entire contents of which are hereby incorporated by reference.

### FIELD OF TECHNOLOGY

The following relates to computer-aided design and analysis and more particularly relates to a method and system for generating a design of a product.

### BACKGROUND

In general, various environmental impacts such as energy, water, climate change, human health and ecological toxicity, and other unknown emerging environmental risks are major challenges. With an intention to address these challenges, various environmental and sustainable policies have been applied and/or considered by many companies to ensure that environmental impact from their products are controlled.

An environmental sustainability measurement of the product can be used to indicate the environmental impacts of the product. However, in existing systems, environmental sustainability is typically evaluated after the product is towards the end of its life cycle. For example, various mechanisms are available for handling wastes produced by a product after usage of the product. Further, conventionally, the product is manufactured and then the environmental assessment is performed, e.g., when required for some approvals. Thus, the product may be launched without a proper understanding of its environmental impact.

Documents, which may be useful for understanding the field of technology, include U.S. Pat. Nos. 6,811,344B1 and 5,852,560A.

In light of above, there is a need for generating design(s) of a product by having environmental sustainability considerations.

### SUMMARY

An aspect relates to a method and a system for generating a design of a product based on its impact on the environment.

The aspect of embodiments of the present invention are achieved by a method comprising obtaining a model of the product, wherein the model is associated with a design of the product. The method comprises simulating the model of the product with respect to an environmental sustainability of the product. The model can be a computer-aided design model, a geometrical shape, a pre-determined shape of the product, an engineering model and the like. The method additionally comprises generating simulation results indicative of behavior of the model with respect to the environmental sustainability. In response to the simulation, the behavior of the model with respect to the environmental sustainability can be generated. The simulation results comprise an environmental sustainability index of the product. The environmental sustainability index of the product can be quantified as a value. The method additionally comprises determining whether the environmental sustainability index of the product satisfies an environmental sustainability threshold value. Further, the method comprises generating a modified model the product, if the environmental sustainability index of the product satisfies the environmental sustainability threshold value. The modified model of the product is associated with the design of the product which satisfies the environmental sustainability threshold value. For example, the environmental sustainability threshold value may be a pre-defined value in accordance with a sustainable environmental policy.

Moreover, the method comprises determining one or more parameters affecting the environmental sustainability of the model, if the environmental sustainability index fails to satisfy the environmental sustainability threshold value. The method additionally comprises computing values of the one or more parameters such that the environmental sustainability index satisfies the environmental sustainability threshold value. To satisfy the environmental sustainability threshold value, the values of the parameters affecting the environmental sustainability of the product can be computed. In an embodiment, quantity of material to be used in the product can be determined such that the product satisfies the environmental sustainability threshold value. For example, if 4 kg of carbon is used for the product and the product fails to satisfy the environmental sustainability threshold value, the method may compute or suggest that 2 kg of carbon may be used to satisfy the environmental sustainability threshold value. Although, material (i.e., carbon) is considered as one example, the method can be used to compute values of other parameters affecting the environmental sustainability of the product. Further, the method comprises optimizing the model of the product based on the values of the one or more parameters. Therefore, the values (which define the quantities of the materials and the like) affecting the environmental sustainability of the product can be computed to satisfy the environmental sustainability threshold value for generating the design of the product.

The one or more parameters are associated with at least one of material, dimensions, engineering parameters, design parameters and geometric parameters of the product. Further, the one or more parameters define environmental sustainability of the product based on an impact of use of the product on the environment. For example, various parameters of the product such as emissions, noise, waste or the like can be defined based on specific regional conditions. Thus, the designers can define different requirements based on different regions, which allows the designers to input the requirements related to material, manufacturing usage, transportation and after useful life specific to different regions. Thereby, the proposed method allows the designers to specify different requirements for different regions. Thus, the proposed method and system allows the designers to develop region specific designs.

Additionally, the method comprises generating one or more suggestions related to the one or more parameters based on the information received from knowledge sources for generating the modified model the product, if the computed environmental sustainability index of the product fails to satisfy the environmental sustainability threshold value. For example, the suggestions may include reducing the amount of a certain material, to use renewable materials, or to reuse materials contained in the product. Other examples of suggestions can include increasing energy efficiency, and reducing material toxicity and the like. The design of the product may be automatically generated product based on the generated suggestions.

The proposed method and system can be used by the designers to generate design solutions from environmental perspective along with existing design practices. With inclusion of the parameters related to environmental sustainability of the product, the designers can evaluate the environmental and human health burdens associated with a product, process, or activity by identifying energy, materials used, and emissions released into the environment, from raw material extraction to final product disposition. Therefore, the proposed method and system can be used to generate sustainable designs which meets the environmental sustainability threshold. Thus, environmentally sustainable products can be developed.

Moreover, the method comprises recommending one or more secondary usages of the product based on the information received from the one or more knowledge sources. For example, the components used in aviation industries can be used in automobile industries and the materials used in automobile industry can be used for traffic management such as signboards. Thus, the proposed method and system can be used to recommend one or more secondary usages of the design of the product. Further, the proposed method and system provides suggestions such as efficient ways of disassembly of components, alternative materials to be used for designs, surface painting alternatives and alternatives for material sourcing, region for manufacturing, alternative processes for manufacturing and transportation and sources of energy and so on.

Therein, simulating the model of the product with respect to the environmental sustainability of the product comprises obtaining one or more parameters defining the environmental sustainability of the product. The parameters defining the environmental sustainability of the product may include energy consumption, potable water consumption, solid waste production, solid waste production, resource conservation, cleaning chemicals used, and the like and many other parameters related to carbon footprint, air acidification, eco-toxicity, human toxicity and others. The method additionally comprises dynamically updating one or more parameters based on the information received from one or more knowledge sources. The knowledge sources can include but not limited to knowledge graph, historical data, expert knowledge related to designs, unstructured data, information related to past experiences and the like. The knowledge graph may include domain specific knowledge about various designs of the product and relationships between design qualification metrics (i.e., functionality, performance, reliability) of the product. The expert knowledge may include information obtained from people who design products and services, and the customers who consume them, which may be obtained in terms of geography, time, and technical knowledge. The past experiences may include experiences of individuals by virtue of their intimate involvement with and knowledge of the product. The unstructured data may include additional or supplementary information related to design(s) of the product. The information from the knowledge sources 308 are provided to the LCA engine 306 for performing the Life Cycle Assessment (LCA).

In an embodiment, the LCA is performed on the model of the product with respect to the environmental sustainability. The one or more parameters may be updated using the information received from the one or more knowledge sources through artificial intelligence and machine learning models. In response to performing the LCA, the LCA results can be determined. Design strategies for generating the design of the product (i.e., modified design of the product) based on results of the LCA. The LCA results may indicate that usage of a certain material or product shows a high score in global warming. As the LCA is performed at the design phase of the product, the method allows the designers to generate the design(s) based on analysis of results of the LCA.

Further, the method comprises computing the environmental sustainability of the product by analyzing the results of the LCA. Thus, by computing the environmental sustainability of the product by performing the LCA at the early stages of the design, the method allows the designers to modify or update the designs to develop environmentally friendly products.

The aspect of embodiments of the present invention are also achieved by a system comprising one or more processing units, a product environmental database coupled to the processing units, a memory coupled to the processing units. The memory comprising a design module configured for simulating a model of the product with respect to environmental sustainability of the product. Further, the design module is configured for generating simulation results indicative of behavior of the model with respect to the environmental sustainability. The simulation results comprise an environmental sustainability index of the product. The design module is configured for determining whether the environmental sustainability index of the product satisfies an environmental sustainability threshold value. Further, the design module is configured for generating a design of the product, if the environmental sustainability index of the product satisfies the environmental sustainability threshold value.

The aspect of embodiments of the present invention are also achieved by a computer-program product comprising a non-transitory computer readable medium, having thereon a computer program comprising program instructions, the computer program being loadable into a processing unit and configured to cause execution of the method as described above.

### BRIEF DESCRIPTION

Some of the embodiments will be described in detail, with reference to the following figures, wherein like designations denote like members, wherein:

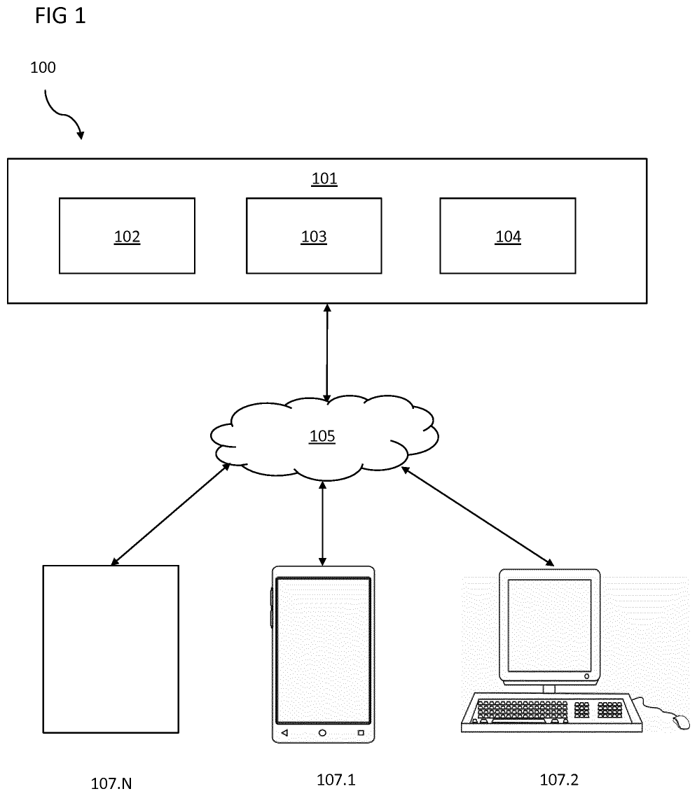

FIG. 1 illustrates a block diagram of a system, according to an embodiment of the present invention;

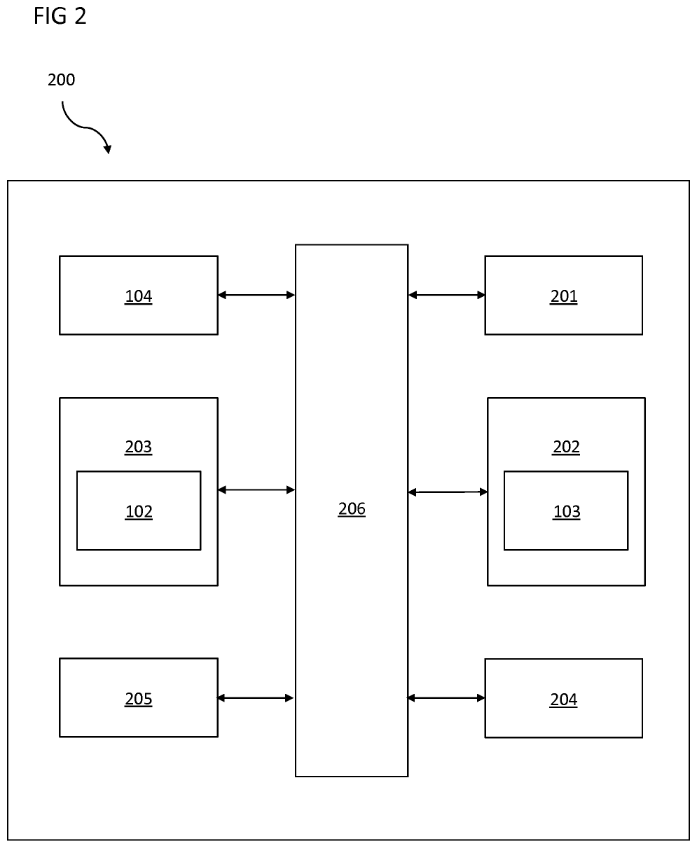

FIG. 2 illustrates a block diagram of another system, according to an embodiment of the present invention;

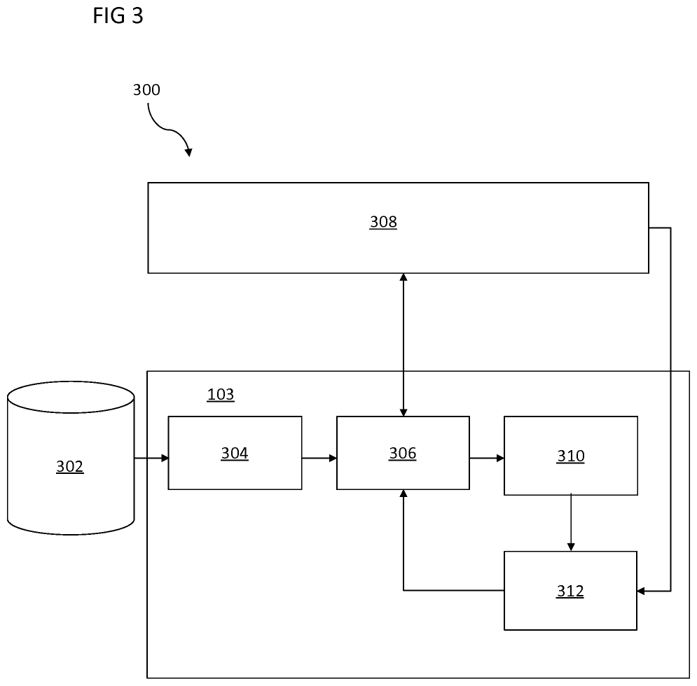

FIG. 3 illustrates a block diagram depicting a design module, according to an embodiment of the present invention;

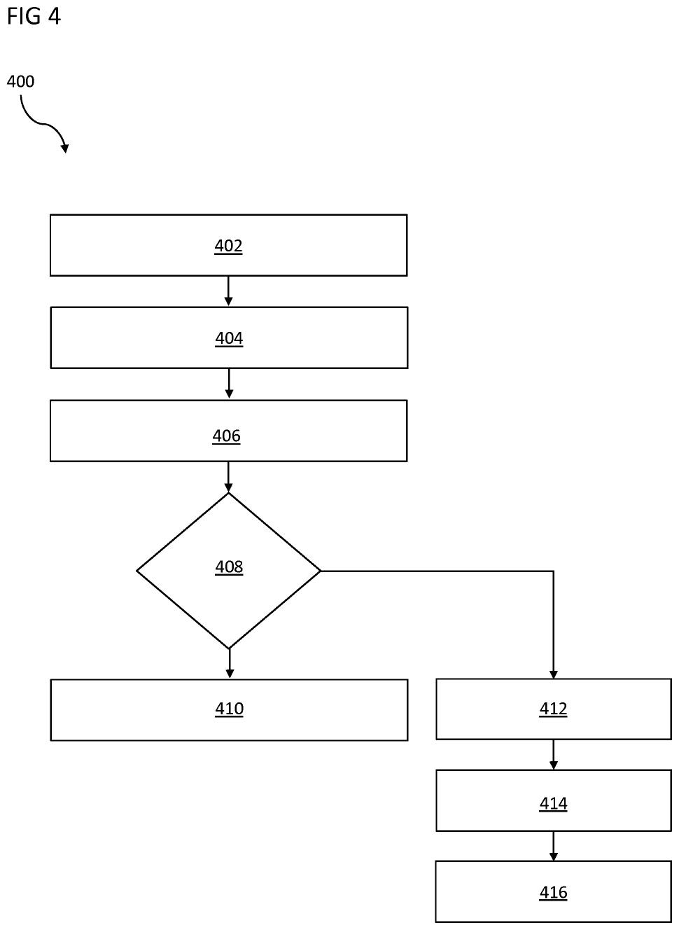

FIG. 4 is a flow chart illustrating a method for generating a design of the product, according to an embodiment of the present invention;

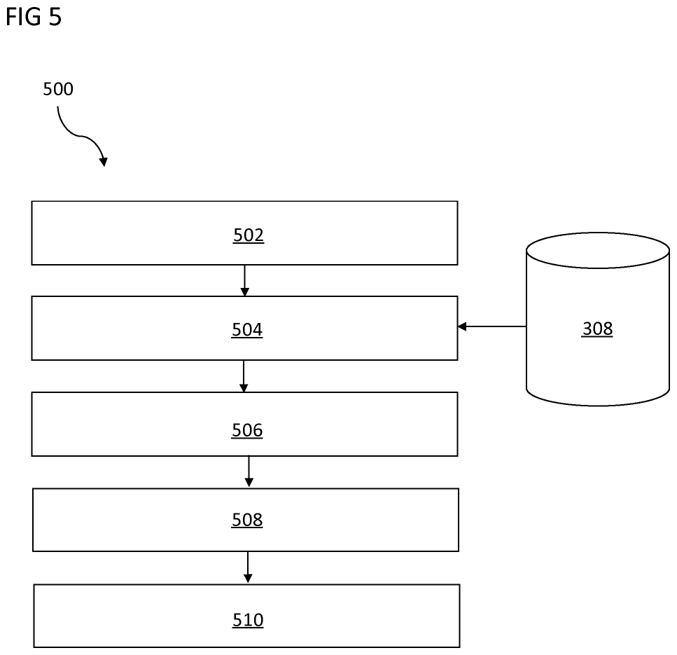

FIG. 5 is a flow chart illustrating a method for computing an environmental sustainability of the product during design phase of the product, according to an embodiment of the present invention;

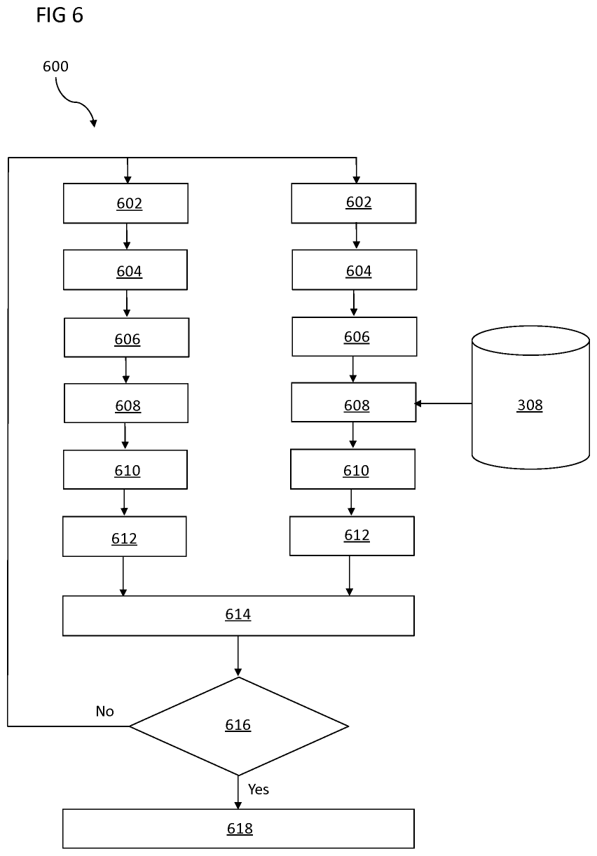

FIG. 6 illustrates various steps for performing Life Cycle Assessment (LCA) during design phase of the product, according to an embodiment of the present invention; and

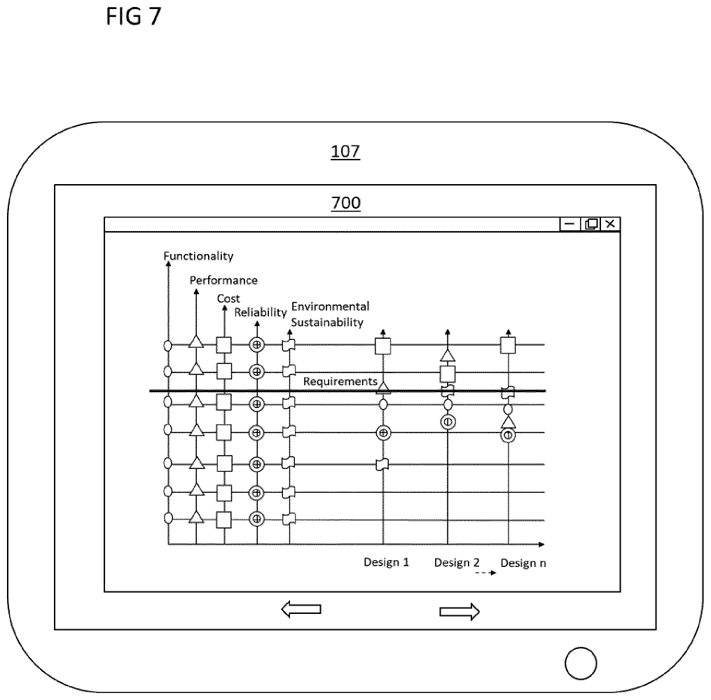

FIG. 7 is a graphical representation of design qualification metrics along with estimated environmental sustainability for each design, according to an embodiment of the present invention.

### DETAILED DESCRIPTION

Various embodiments of the present disclosure will now be described in detail with reference to the accompanying drawings. In the following description, specific details such as detailed configuration and components are merely provided to assist the overall understanding of these embodiments of the present disclosure. Therefore, it should be apparent to those skilled in the art that various changes and modifications of the embodiments described herein can be made without departing from the scope and spirit of the present disclosure. In addition, descriptions of well-known functions and constructions are omitted for clarity and conciseness.

Also, the various embodiments described herein are not necessarily mutually exclusive, as some embodiments can be combined with one or more other embodiments to form new embodiments.

In the following description, for the purpose of explanation, numerous specific details are set forth to provide thorough understanding of one or more embodiments. It may be evident that such embodiments may be practiced without these specific details.

In an embodiment, the environmental sustainability index of the product can be computed during the design phase of the product and the environmental sustainability index of the product can be quantified as a value. Once the design qualification metrics such as functionality, performance, cost reliability and the environmental sustainability index meet the pre-defined requirements, then the design(s) are generated and the product is developed. The pre-defined requirements may include, for example, standard values for functionality, performance, cost, reliability, and the environmental sustainability index. The pre-defined requirements may have respective standard values as decided or set by the designers. For example, ‘performance’ of the product may be set to a value and likewise for each of the pre-defined requirements, corresponding values are set by the designers.

In an embodiment, the design qualification metrics are computed quantitatively, and the design is generated based on the computed design qualification metrics. In addition to the design qualification metrics, various other requirements based on the application and usage of the product may be included for generating the design of the product.

In an embodiment, the values of the design qualification metrics are compared with the respective standard values to generate the design which meets the pre-defined requirements.

FIG. 1 is a block diagram of a system 100, according to an embodiment of the present invention. The system 100 includes a server 101 and a plurality of client devices such as electronic devices 107.1, 107.2 and so on to 107.N (herein after referred as electronic device 107). Each of the client devices 107.1 to 107. N is connected to the server 101 via a network 105 (e.g., Local Area Network (LAN), Wide Area Network (WAN), Wi-Fi, etc.).

The server 101 may include hardware, software, or firmware components. In an embodiment, the server 101 includes a product environmental database 102, a design module 103, and a network interface 104.

For example, the product environmental database 102 stores a plurality of parameters representing environmental sustainability indicators corresponding to a sustainable environmental policy. The environmental sustainability indicators may include parameters indicating energy consumption, potable water consumption, solid waste production, solid waste production, resource conservation, cleaning chemicals used, and the like. The product environmental database 102 may include many other parameters related to carbon footprint, air acidification, eco-toxicity, human toxicity and others.

In some embodiments, the product environmental database 102 may also store information related to various products and their models which are obtained from multiple knowledge sources including but not limited to knowledge graphs, historical data, unstructured data and the like.

In an embodiment, the design module 103 communicates with the product environmental database 102 to obtain the parameters of the product for generating a design of the product based on the environmental sustainability index.

Alternatively, the design module 103 may obtain information from various knowledge sources such as knowledge graph, historical data, unstructured data, and the like which are hosted in a remote server or a cloud by communicating through the network interface 104.

Although not shown in FIG. 1, the server 101 includes a processor, a memory and a storage unit. The memory includes the design module 103 stored in the form of machine-readable instructions executable by the processor. When executed by the processor, the design module 103 causes the processor to generate a design of the product, based on environmental sustainability index such that the generated design meets the environmental sustainability threshold value along with pre-defined requirements associated with the product. Method steps performed by the processor to achieve the above functionality are described in greater detail in FIGS. 3 and 4.

The client devices such as the electronic devices 107.1-N are provided with input units and display units, respectively. Users of the electronic devices 107.1-N can access the server 101 via a graphical user interface displayed on the respective display units. The graphical user interfaces may be specifically designed for accessing the design module 103 in the server 101.

The network 105 may include, but are not limited to, any one or more different types of communications networks such as, for example, cable networks, public networks (e.g., the Internet), private networks (e.g., frame-relay networks), wireless networks, cellular networks, telephone networks (e.g., a public switched telephone network), cloud-based networks, or any other suitable private or public packet switched or circuit switched networks. Such network(s) may have any suitable communication range associated therewith and may include, for example, global networks (e.g., the Internet), metropolitan area networks (MANs), wide area networks (WANs), local area networks (LANs), or personal area networks (PANs).

In addition, the network interface 104 may include communication links and associated networking devices (e.g., link-layer switches, routers, etc.) for transmitting network traffic over any suitable type of medium including, but not limited to, coaxial cable, twisted-pair wire (e.g., twisted-pair copper wire), optical fiber, a hybrid fiber-coaxial (HFC) medium, a microwave medium, a radio frequency communication medium, a satellite communication medium, or any combination thereof.

In an exemplary operation, a user of the electronic device 107.1 may send a request to the server 101 to generate a design of a product (e.g., a car, a bottle, a rotary blade of a turbine and so on) via a graphical user interface provided to the user. The server 101 may prompt the user to provide various parameters of the product on the graphical user interface. Accordingly, the user may input the parameters of the product which can include design requirements, and the parameters which can include environmental sustainability indicators related to the product, via the graphical user interface. The electronic device 107.1 sends the parameters of the product to the server 101 via the network 105. Accordingly, the processor in the server 101 obtains a model of the product, for example from the product environmental database. The model can be a computer-aided design model, a geometrical shape, a pre-determined shape, an engineering model and the like. Further, the processor performs simulation of the model of the product with respect to the environmental sustainability of the product. The simulation can be performed with the obtained one or more parameters and the information received from the one or more knowledge sources which include but not limited to knowledge graphs, historical data, unstructured data, domain knowledge related to designs and the like. It should be noted that the processor computes the environmental sustainability index of the product. Further, the processor may determine whether the environmental sustainability index of the product satisfies the environmental sustainability threshold value. The processor generates a design of the product, if the environmental sustainability index of the product satisfies the environmental sustainability threshold value.

Additionally, the processor outputs the generated design on the display unit of the electronic device 107.1. For example, the graphical user interface on the electronic device 107.1 may display the generated design along with the computed values of performance, reliability, cost functionality and environmental sustainability index of the design. Further, the processor may output various secondary usages of the product using the information received from the knowledge sources including knowledge graph, historical data, unstructured data and the like. Also, the processor may store information associated with generated design in the product environmental database 102.

In an embodiment, the processor may validate whether the generated design satisfies the environmental sustainability threshold. A plurality of users can simultaneously validate whether the generated design satisfies the environmental sustainability threshold using the system 100 i.e., by accessing the server 101 from the electronic devices 107.1-N. This eliminates the need for installing the design module 103 on each of the electronic devices 107.1-N.

In accordance with the foregoing description, the design module 103 may be implemented in a cloud computing environment, wherein the design module 103 is hosted in a cloud server. The various embodiments pertaining to the design module 103 are described in greater detail in FIG. 3.

FIG. 2 illustrates a block diagram of another system 200, according to an embodiment of the present invention. The system 200 may be a personal computer, a laptop computer, a tablet, and the like. The system 200 is another implementation of the system 100 of FIG. 1, wherein the design module 103 resides for example, in an electronic device 107.2 (i.e., a personal computer).

The system 200 may include processing unit 201, one or more memory devices 202 (referred to herein as memory 202), storage unit 203, an input unit 204, an output unit 205 and a network 2 0 interface 104. The system 200 may further include one or more buses 206 that functionally couple various components of the system 200.

The processing unit 201, as used herein, means any type of computational circuit, such as, but not limited to, a microprocessor, a microcontroller, a complex instruction set computing 2 5 microprocessor, a reduced instruction set computing microprocessor, a very long instruction word microprocessor, an explicitly parallel instruction computing microprocessor, a graphics processor, a digital signal processor, or any other type of processing circuit. The processing unit 201 may also include embedded controllers, such as generic or programmable logic devices or arrays, application specific integrated circuits, single-chip computers, and the like.

The memory 202 may be volatile memory and non-volatile memory. The memory 202 may be coupled for communication with the processing unit 201. The memory 202 may include volatile memory (memory that maintains its state when supplied with power) such as random-access memory (RAM) and/or non-volatile memory (memory that maintains its state even when not supplied with power) such as read-only memory (ROM), flash memory, ferroelectric RAM (FRAM), and so forth. Persistent data storage, as that term is used herein, may include non-volatile memory. In certain example embodiments, volatile memory may enable faster read/write access than non-volatile memory. However, in certain other example embodiments, certain types of non-volatile memory (e.g., FRAM) may enable faster read/write access than certain types of volatile memory. In certain example, the storage unit 203 may be equivalent to the memory 202. In various implementations, the memory 202 may include multiple different types of memory such as various types of static random-access memory (SRAM), various types of dynamic random-access memory (DRAM), various types of unalterable ROM, and/or writeable variants of ROM such as electrically erasable programmable read-only memory (EEPROM), flash memory, and so forth. The memory 202 may include main memory as well as various forms of cache memory such as instruction cache(s), data cache(s), translation lookaside buffer(s) (TLBs), and so forth. Further, cache memory such as a data cache may be a multi-level cache organized as a hierarchy of one or more cache levels (L1, L2, etc.). In the present embodiment, the memory 202 includes a design module 103 stored in the form of machine-readable instructions on any of the above-mentioned storage media and may be in communication to and executed by processing unit 201. When executed by the processing unit 201, the design module 103 causes the processing unit 201 to generate a design of the product, if the environmental sustainability index of the product satisfies the environmental sustainability threshold value. For example, the environmental sustainability threshold value may be a pre-defined value in accordance with a sustainable environmental policy. Further, the generated design also satisfies the pre-defined requirements in terms of functionality, performance, cost and reliability along with the environmental sustainability threshold. Method steps performed by the processing unit 201 to achieve the above functionality are described in greater detail in FIG. 4.

The storage unit 203 may be a non-transitory storage medium which stores a product environmental database 102. The product environmental database 102 stores a plurality of environmental sustainability indicators corresponding to a sustainable environmental policy. The environmental sustainability indicators may include several parameters indicating energy consumption, potable water consumption, solid waste production, social commitment, resource conservation, cleaning chemicals used, or the like. The product environmental database 302 may include many other parameters related to carbon footprint, air acidification, eco-toxicity, human toxicity and others. The product environmental database also stores information related to the product.

The input unit 204 may include input means such as keypad, touch-sensitive display, camera (such as a camera receiving gesture-based inputs), etc. capable of receiving input signal such as a file including requirements associated with the product. The output unit 205 may be means for displaying a graphical user interface which visualizes a multi-dimensional representation of the computed design qualification metrics based on the obtained requirements of the product. The bus 206 acts as interconnect between the processing unit 201, the memory 202, the storage unit 203, the input unit 204, and the output unit 205. The bus(es) 206 may include at least one of a system bus, a memory bus, an address bus, or a message bus, and may permit the exchange of information (e.g., data (including computer-executable code), signalling, etc.) between various components of the design module 103. The bus(es) 206 may include, without limitation, a memory bus or a memory controller, a peripheral bus, an accelerated graphics port, and the like.

The network interface 104 may include communication links and associated networking devices (e.g., link-layer switches, routers, etc.) for transmitting network traffic over any suitable type of medium including, but not limited to, coaxial cable, twisted-pair wire (e.g., twisted-pair copper wire), optical fiber, a hybrid fiber-coaxial (HFC) medium, a microwave medium, a radio frequency communication medium, a satellite communication medium, or any combination thereof. The system 200 communicates with the network 105 shown in FIG. 1, through the network interface 104.

Those of ordinary skilled in the art will appreciate that the hardware depicted in FIG. 2 may vary for particular implementations. For example, other peripheral devices such as an optical disk drive and the like, Local Area Network (LAN)/Wide Area Network (WAN)/Wireless (e.g., Wi-Fi) adapter, graphics adapter, disk controller, input/output (IO) adapter also may be used in addition or in place of the hardware depicted. The depicted example is provided for the purpose of explanation only and is not meant to imply architectural limitations with respect to the present disclosure.

The system 200 in accordance with the embodiments of the present disclosure includes an operating system employing a graphical user interface. The operating system permits multiple display windows to be presented in the graphical user interface simultaneously with each display window providing an interface to a different application or to a different instance of the same application.

Disclosed embodiments provide systems and methods that generate a design of a product considering the environmental sustainability of the product. Disclosed techniques may generate the design of the product which satisfies the environmental sustainability threshold value along with other pre-defined requirements in terms of performance, functionality, cost, and reliability. Further, various recommendations may be provided for one or more secondary usages of the product based on information received from the knowledge sources including but not limited to knowledge graph, unstructured data, historical data, and the like.

FIG. 3 illustrates a block diagram depicting a design module 103 in further detail. The design module 103 includes various components for generating design of the product, according to an embodiment of the present invention. As depicted in FIG. 3, the design module 103 includes a parameter selection component 304, a life cycle assessment (LCA) engine 306, an LCA analyzer 310, and a recommendation component 312. The design module 103 is communicatively coupled to the product environmental database 102 and one or more knowledge sources 308. The knowledge sources 308 may be present external to the system 200, for example, in a remote server or in a cloud computing environment. Alternatively, the knowledge sources 308 may be present in the storage of the electronic devices 107.1-N. In some embodiments, the knowledge sources 308 may be present at the server 101 and/or in the product environmental database 102. The design module 103 learns using information obtained from the knowledge sources 308 through artificial intelligence models to generate the design of the product that satisfies the environmental sustainability threshold value and generates various suggestions related to the parameters of the product, if the generated design fails to satisfy the environmental sustainability threshold value.

The product environmental database 102 contains parameters representing environmental sustainability indicators corresponding to a sustainable environmental policy. The environmental sustainability indicators may include several parameters indicating energy consumption, potable water consumption, solid waste production, resource conservation, cleaning chemicals used, or the like. The product environmental database 102 may include many other parameters related to carbon footprint, air acidification, eco-toxicity, human toxicity and others. In some embodiments, the product environmental database 102 may also store information related to various products and their associated designs. A set of parameters representing the environmental sustainability indicators may be obtained from the product environmental database 102 for generating the design of the product.

The parameter selection component 304 can be configured to obtain a model of the product and the parameters representing environmental sustainability indicators of the product from the product environmental database 102. For example, the parameters may be obtained from the product environmental database 102. The selected parameters represent respective environmental sustainability indicators for the product. The selected parameters are the sustainability requirements, which are set and/or decided by the user. For example, the parameters or sustainability requirements may include a CO2 footprint reduction and a total hazardous waste emission reduction. Other sustainability requirements may include, but are not limited to, percentage of renewable energy, removal of toxic substances, design for efficient distribution and the like. It should be noted that the parameters or the requirements are selected based on functionality of the product, application, and usage of the product. Therefore, the parameters may vary for each product based on the functionality of the product, application, and usage of the product.

The LCA engine 306 can be configured to simulate the model of the product (i.e., by performing life cycle assessment, LCA) with respect to the environmental sustainability of the product with the parameters obtained from the product environmental database 102. The LCA engine 306 can be configured to evaluate the environmental and human health burdens associated with the product by identifying energy, materials used, and emissions released into the environment, from raw material extraction to final product disposition.

Further, the LCA engine 306 can be configured to obtain a plurality of parameters associated with a lifecycle of the product. The plurality of parameters associated with the life cycle of the product includes material, manufacturing, usage, transportation, and after useful life of the product. With the parameters, the LCA engine 306 performs initial LCA to determine the environmental sustainability index of the product.

In an embodiment, the LCA engine 306 can be configured to receive information from various knowledge sources 308. The LCA engine 306 can be configured to update the parameters with the information received from the knowledge sources. For example, the knowledge sources 308 include knowledge graphs, historical data, unstructured data, expert knowledge related to designs and the like. The knowledge graph may include domain specific knowledge about various designs of the product and relationships between design qualification metrics of the product. The expert knowledge may include information obtained from people who design products and services, and the customers who consume them, which may be obtained in terms of geography, time, and technical knowledge, or in terms of worldview, goals, and daily concerns. The past experiences may include experiences of individuals by virtue of their intimate involvement with and knowledge of the product. The unstructured data may include additional or supplementary information related to design(s) of the product.

The information from the knowledge sources 308 are provided to the LCA engine 306 for performing the LCA. The LCA engine 306 performs the LCA to determine the environmental sustainability index of the product based on the obtained parameters and the information received from the knowledge sources 308. Further, the LCA engine 306 can be configured to generate simulation results indicative of the behavior of the model with respect to environmental sustainability of the product. The simulation results include the environmental sustainability index of the product. The LCA is performed to assess environmental impacts associated with the stages of a product's life from raw material extraction through materials processing, manufacture, distribution, use, repair and maintenance, and disposal or recycling. For example, the LCA engine 306 computes the environmental sustainability index of the product (e.g., a bottle) is 0.4 when plastic is used as a material for manufacturing the bottle. In another example, the LCA engine 306 computes the environmental sustainability of the product is 0.8 when copper is used as a material for manufacturing the bottle. Thus, the environmental sustainability of the product can be computed by the LCA engine 306 based on the obtained parameters related to materials processing, manufacture, distribution, use, repair, and maintenance.

The various stages of LCA, performed by the LCA engine 306 are described herein. For example, the LCA is performed in four phases such as goal and scope, inventory analysis, impact assessment, and interpretation. In the goal and scope phase, the goals and scope of the LCA are defined. During inventory analysis, environmental inputs and outputs associated with a product, such as the use of raw materials and energy, the emission of pollutants and the waste streams are provided. During impact assessment, relevant results are derived to make better decisions. For example, the environmental impacts are classified and evaluated. At interpretation phase, the LCA results are validated. The output of the LCA engine 306 is provided to the LCA results analyzer 310 for analysing the results of the LCA.

The LCA results analyzer 310 can be configured to analyze the LCA results received from the LCA engine 306. In an embodiment, the LCA results analyzer 310 can be configured determine whether the generated design satisfies the environmental sustainability threshold value by comparing the computed environmental sustainability index with the environmental sustainability threshold value.

In an embodiment, the recommendation engine 312 includes information about materials and their impact on the environment. For example, the recommendation engine 312 can receive the LCA results from the LCA results analyzer 310, and the recommendation engine 312 can be configured to generate or output a list of suggestions related to the materials to be used for the design and design strategies that can be used for designing the product. For example, the recommendation engine 312 can utilize the LCA results and the information from the knowledge sources 308 to output the design strategies for generating the design of the product, such as indicating that a certain material or product shows a high score in global warming. The sustainable design strategy received from the recommendation engine 312 can be to reduce the amount of a certain material, to use renewable materials, and/or to reuse materials contained in the product alternative processes for manufacturing and transportation.

Other examples of design strategies can include increasing energy efficiency and reducing material toxicity. Accordingly, based on the results of the LCA, the recommendation engine 312 generates suggestions for generating the design. Based on the suggestions from the recommendation engine 312, the parameters, for example material of the product can be modified to generate a design that satisfies the environmental sustainability threshold value along with the pre-defined requirements in terms of functionality, performance, cost, and reliability. Therefore, the recommendations from the recommendation engine 312 are considered and then the LCA is repeated to generate the design that meets the pre-defined requirements.

Further, the recommendation engine 312 may provide one or more suggestions related to secondary usage of the product using the information received from the knowledge sources 308. For example, components used in aviation industries can be used in automobile industries, and the materials used in automobile industry can be used for traffic management such as signboards.

FIG. 4 is a flow chart 400 illustrating a method for generating a design of the product, according to an embodiment of the present invention. At step 402, the model of the product, which is associated with the design of the product is obtained. At step 404, the model of the product is simulated with respect to the environmental sustainability of the product. The simulation of the model of the product is performed based on the obtained one or more parameters and the information received from the knowledge sources 308.

The parameters of the product may include environmental sustainability indicators related to the product. In an embodiment, the parameters of the product may be obtained as an input from the user via a user interface displayed on the electronic device 107.1. In another embodiment, the parameters indicative of an environmental sustainability of the product of the product may be obtained automatically without user input.

The parameters are the sustainability requirements decided by the user. For example, the sustainability requirements may include a CO2 footprint reduction, a total hazardous waste emission reduction, and other requirements as decided by the user. The set of parameters representing the environmental sustainability indicators can be displayed for selection by the user.

In an embodiment, various stages of life cycle of the product is simulated to analyze the behavior of the product with respect to the environmental sustainability of the product. The environmental sustainability index of the product can be determined by analyzing the simulation results. The results of the simulation can be provided in text and graphical forms. Along with the environmental sustainability index of the product, design qualification metrics such as functionality, performance, cost and reliability of the product may be determined by simulating the model of the product.

In an embodiment, the ‘functionality’ of the product can be quantified or measured by performing a simulation to determine whether the product achieves its intended function. Various simulation tools may be used to determine whether the product achieves its intended function and thereby quantifying the functionality of the product. For example, one dimensional simulation or a zero-dimensional simulation can be used determine whether the product achieves its intended function.

For example, the ‘performance’ of the product can be quantified by performing a numerical simulation. In another example, the ‘cost’ of the product can be computed using cost models and the ‘reliability’ of the product can be computed using reliability models. Thus, the design qualification metrics including functionality, performance, cost, and reliability are computed by performing simulations with the obtained parameters or the requirements of the product.

In an embodiment, the life cycle of the product is simulated with the obtained parameters to determine the environmental sustainability index for product. The process of simulating the life cycle of the product involves providing various parameters indicative of environmental sustainability of the product at various stages of simulation. For example, various user interface (UI) screens may be provided to the user in which the parameters or requirements (such as material, manufacturing, usage, transportation and after useful life of the product) and data relating to assessment scope, assessment goals, and access can be obtained as input from the user.

The UI may include text boxes, list boxes, and other GUI objects and the like which facilitates user to provide various inputs for performing the LCA.

In general, setting the assessment scope includes defining requirements or boundaries for the assessment. The requirements can be stored and selected. The user may also select life cycle phases and transportation elements to be included in the assessment. Examples include materials production (e.g., extraction from nature, refining, and delivery at factory gate), processing of material, packaging materials, energy consumption during use, other materials during use, and end-of-life scenarios. Transportation elements can include, for example, the transportation from refining factory to manufacturing factory, transportation through distribution networks, transportation from retail site to point of use, and transportation to end-of-life destination. Further, the user can enter assessment goals. In general, the goals are defined by an organization or a company and can be entered through a text box. For example, the goals may include the organization's environmental goals as they relate to product development such as increase recycling or eliminate hazardous materials. Goals may also be assigned for a particular product assessment, such as reducing energy consumption during use or increasing energy efficiency associated with the product. Thus, the LCA is performed initially with the input data as described above.

Further, the parameters which denote the environmental sustainability indicators are dynamically updated for simulating the life cycle of the product based on information received from the knowledge sources 308, which include but not limited knowledge graphs, historical data, unstructured data and the like. Thus, the life cycle of the product is simulated with the updated input data to evaluate the environmental sustainability index for the obtained parameters. The input data may be updated using information received from the knowledge sources 308 through artificial intelligence and machine learning models. Therefore, the life cycle of the product is simulated with updated parameters, as the knowledge sources 308 contains domain knowledge of designs, historical data of designs and unstructured data. Various suggestions or alternatives can be derived from the simulation of the life cycle of the product. For example, consider the product to be turbines, then the suggestions can include manufacturing of turbines can be environmentally friendly in Europe compared to India due to the source of electricity. In another example, suggestions can include manufacturing of turbines in rainy season is a better option due to availability of electricity.

At step 406, the simulation results indicative of the behavior of the model with respect to environmental sustainability are generated, the simulation results comprise the environmental sustainability index of the product. The environmental sustainability index is quantified as a value which indicates the environmental sustainability of the product.

At step 408, it is determined whether the environmental sustainability index of the product satisfies the environmental sustainability threshold value. For example, the computed environmental sustainability index is compared with the environmental sustainability to determine whether the environmental sustainability index satisfies the environmental sustainability threshold.

In another embodiment, the values of the design qualification metrics are compared with threshold values of each of the pre-defined requirements to determine whether the generated design(s) satisfy the pre-defined requirements. For example, the quantified values of the design qualification metrics such as functionality, performance, cost, reliability and environmental sustainability index are compared with respective threshold values of the pre-defined requirements to determine whether the generated design meets the pre-defined requirements.

At step 410, the modified model of the product is generated if the computed environmental sustainability index of the product satisfies the environmental sustainability threshold value. The modified model of the product is associated with the design of the product which satisfies the environmental sustainability threshold value. Thus, the generated design satisfies the environmental sustainability threshold value and therefore, an environmentally sustainable product can be developed.

In case, at step 408, if it is that the environmental sustainability index of the product fails to satisfy the environmental sustainability threshold value, then at step 412, the one or more parameters affecting the environmental sustainability of the product are determined. For example, the material of the product, the quantity of the material may affect the environmental sustainability of the product.

At step 414, the values of the parameters are computed such that the environmental sustainability index satisfies the environmental sustainability threshold value. To meet the environmental sustainability threshold value, the values of the parameters affecting the environmental sustainability of the product can be determined. The quantity of material to be used in the product can be determined such that the product satisfies the environmental sustainability threshold value. For example, 4 kg of carbon is used in the product and the product fails to satisfy the environmental sustainability threshold value, the simulation results may compute or suggest that 2 kg of carbon may be used to satisfy the environmental sustainability threshold value. Therefore, the values (which define the quantities of the materials) can be computed in order satisfy the environmental sustainability threshold value for generating the product.

At step 416, the model of the product is optimized based on the values of the one or more parameters. The design of the product may be generated in accordance with the values of the one or more parameters to meet the environmental sustainability threshold value.

In an embodiment, one or more suggestions related to the parameters are generated. For example, the suggestions can be to reduce the amount of a certain material, to use renewable materials, and/or to reuse materials contained in the product and alternative processes for manufacturing and transportation. Further, the design is generated automatically based on the suggestions.

FIG. 5 is a flow chart 500 illustrating a method for computing the environmental sustainability of the product during design phase of the product, according to an embodiment of the present invention. At step 502, the model and one or more parameters are obtained. The one or more parameters of the product are obtained from the product environmental database 102. The one or more parameters represent the environmental sustainability indicators for the product. At step 504, the environmental sustainability of the product is computed based on the obtained set of parameters and the information received from the one or more knowledge sources.

In an embodiment, the environmental sustainability of the product is computed by performing LCA of the product using the information received from the knowledge sources 308. The parameters associated with the product are dynamically updated with the information received from the knowledge sources 308 while simulating the model of the product.

At step 506, the selected parameters are quantified for sustainability measurement. For example, the values for the selected parameters can be obtained in response to performing the LCA. If the selected parameters are parameter 1, parameter 2 and parameter n, then the parameter 1 can be quantified as a value ‘x’, parameter 2 can be quantified as a value ‘y’ and the parameter n can be quantified as value ‘n’.

At step 508, a weighted average of the selected parameters is calculated. Each of the selected parameter is assigned a weight and then the assigned weight is multiplied with the quantified value of that parameter and then those values are added to determine the weighted average of the selected parameters.

At step 510, the environmental sustainability of the product is measured as the weighted average of the selected parameters. Thus, the environmental sustainability value is computed for the product based on the set of parameters.

In some embodiments, the environmental sustainability value for the product may be represented graphically along with other design qualification metrics such as functionality, performance, cost and reliability to generate the design that meets the pre-defined requirements.

FIG. 6 illustrates various steps for performing LCA during design phase of the product, according to an embodiment of the present invention. In an embodiment, the proposed method and system can be used to select the design from a plurality of designs. The designs are tested by simulating the life cycle of the product to select the design which meets the pre-defined requirements. Initially, at step 602, design 1 and design 2 are extracted and the design requirements associated with the product are obtained at step 604. At step 606, a set of parameters are selected for each design. For example, a set of parameters may be obtained for design 1 and design 2 from the product environmental database 102. The obtained parameters represent respective environmental sustainability indicators for the designs. The obtained parameters are the sustainability requirements, which are set and/or decided by the designers. The inputs for the life cycle of the product are provided for each design at step 608. Further, the information from the knowledge sources 308 are obtained as inputs for performing the LCA. At step 610, life cycle of the product is simulated using input data to compute the environmental sustainability value for the obtained one or more parameters. At step 612, LCA results are obtained for each design. The results of the LCA are compared with the pre-defined requirements at step 614. If it is determined that the designs meet the pre-defined requirements at step 616, then at step 618, at least one design from the design 1 and design 2 are selected for further improvements. In case, it is determined that both the designs fail to meet the pre-defined requirements at step 616, then the designs may be altered by the designers and then the LCA is performed for each design to select the design that meets the pre-defined requirements.

FIG. 7 is a graphical representation of design qualification metrics along with estimated environmental sustainability for each design, according to an embodiment of the present invention. As depicted in FIG. 7, the design qualification metrics including environmental sustainability for each design are presented on a user interface 700 displayed on the electronic device 107. The comparison of values for each requirement can be performed on the X-axis. Since the computed requirements are quantitative in nature; it becomes easier for the designers to derive trade-off between the various requirements and to select a design from the available designs. Thus, the proposed method and system enables the designers to compare all the values representing respective requirements for generating a design according to given requirements.

The embodiments disclosed herein can be implemented through at least one software program running on at least one hardware device and performing network management functions to control the elements. The elements shown in FIGS. 1 through 7 include blocks, which can be at least one of a hardware device, or a combination of hardware device and software module.

The foregoing description of the specific embodiments will fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of embodiments, those skilled in the art will recognize that the embodiments herein can be practiced with modification within the spirit and scope of the embodiments as described herein.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A method for generating a design of a product, the method comprising:
obtaining a model of the product, wherein the model is associated with a design of the product;
simulating the model of the product with respect to an environmental sustainability of the product; generating simulation results indicative of behavior of the model with respect to the environmental sustainability, wherein the simulation results comprise an environmental sustainability index of the product;
determining whether the environmental sustainability index of the product satisfies an environmental sustainability threshold value; and
generating a modified model of the product, if the environmental sustainability index of the product satisfies the environmental sustainability threshold value.

2. The method according to claim 1, further comprising:
determining one or more parameters affecting the environmental sustainability of the product based on the model, if the environmental sustainability index fails to satisfy the environmental sustainability threshold value;
computing one or more parameter values such that the environmental sustainability index satisfies the environmental sustainability threshold value; and optimizing the model of the product based on the one or more parameter values.

3. The method according to claim 1, further comprising generating one or more suggestions related to the one or more parameters based on information received from one or more knowledge sources, if the environmental sustainability index of the product fails to satisfy the environmental sustainability threshold value.

4. The method according to claim 2, wherein the one or more parameters are associated with at least one of material, dimensions, engineering parameters, design parameters and geometric parameters of the product.

5. The method according to claim 2, wherein the one or more parameters define environmental sustainability of the product based on an impact of use of the product on the environment.

6. The method according to claim 2, wherein simulating the model of the product with respect to the environmental sustainability of the product comprises:
obtaining the one or more parameters defining the environmental sustainability of the product;
dynamically updating the one or more parameters based on the information received from the one or more knowledge sources;
performing a Life Cycle Assessment, LCA, of the product with the updated parameters; and computing the environmental sustainability index of the product by analyzing the results of the LCA.

7. The method according to claim 1, further comprising recommending one or more secondary usages of the product based on the information received from the one or more knowledge sources.

8. A system for generating a design of a product, the system comprising:
one or more processing units;
a product environmental database coupled to the processing units; and
a memory coupled to the processing units, wherein the memory a design module configured for performing the method according to claim 1.

9. A computer program product, comprising a computer readable hardware storage device having computer readable program code stored therein, said program code executable by a processor of a computer system to implement a method comprising a non-transitory computer readable medium, having therein a computer program comprising program instructions, the computer program being loadable into a processing unit and configured to cause execution of the method according to claim 1.
